(19) United States
(12) Patent Application Publication
(10) Pub. No.: US 2015/0311409 A1
(43) Pub. Date: Oct. 29, 2015

(54) DISPLAY PANEL AND MOTHER BOARD INCLUDING THE SAME

(71) Applicant: Au Optronics Corporation, Hsinchu (TW)

(72) Inventors: Chen-Shuo Huang, Taoyuan County (TW); Chia-Hsun Tu, Hsinchu County (TW); Cheng-Liang Wang, Hsinchu County (TW); Shih-Hsing Hung, Hsinchu County (TW); Meng-Ting Lee, Taipei City (TW)

(21) Appl. No.: 14/472,359

(22) Filed: Aug. 28, 2014

(30) Foreign Application Priority Data
Apr. 24, 2014 (TW) 103114832

(51) Int. Cl. H01L 33/54; H01L 33/22; H01L 33/56; H01L 33/12

(52) U.S. Cl. CPC H01L 33/54; H01L 33/12; H01L 33/22; H01L 33/56

(57) ABSTRACT

A display panel and a display mother board including the display panel are provided. The display panel includes a substrate, a pixel array, at least one driver circuit, an insulating layer, and a metal wall. The substrate includes a display region and a non-display region, and the non-display region has a driver circuit region and an outer region disposed outside of the driver circuit region. The pixel array and the driver circuit are disposed in the display region and the driver circuit region respectively. The insulating layer is disposed on the substrate and in the non-display region. The metal wall is disposed on the insulating layer and in the outer region, wherein a Poisson's ratio of the metal wall is greater than or equal to 0.32.

### CROSS-REFERENCE TO RELATED APPLICATION

This application claims the priority benefit of Taiwan application serial no. 103114832, filed on Apr. 24, 2014. The entirety of the above-mentioned patent application is hereby incorporated by reference herein and made a part of this specification.

### BACKGROUND

1. Field of the Disclosure

The disclosure relates to a display panel and a mother board thereof, and more particularly relates to a display panel having high reliability and a mother board thereof.

2. Description of Related Art

With the progress in optoelectronics and semiconductor technology, the technology of display panels is becoming mature. Among the various types of displays, flat panel displays have been widely adopted in recent years and have become the mainstream products in place of the conventional cathode ray tube (CRT) displays. Take the liquid crystal display as an example, the active and passive components in the display panel are usually fabricated using inorganic thin films, and generally the inorganic thin films are composed of a brittle material that has no ductility, such as amorphous silicon, polysilicon, silicon oxide and/or silicon nitride. For this reason, when tensile stress is applied on the display panel, crack or peeling may easily occur in the inorganic thin film, which results in damage of the active and/or passive components and affects the reliability of the display panel. In particular, during the process of cutting the display panel from the mother board, crack or peeling may occur near the cut edges of the display panel easily and may very likely extend to a work region of the display panel, causing the reliability of the display panel to drop.

### SUMMARY

The disclosure provides a display panel and a mother board thereof for improving the tensile strength of the display panel so as to increase the reliability of the display panel.

The display panel of the disclosure includes a substrate, a pixel array, at least one driver circuit, an insulating layer, and a metal wall. The substrate includes a display region and a non-display region, and the non-display region has a driver circuit region and an outer region disposed outside the driver circuit region. The pixel array and the driver circuit are disposed in the display region and the driver circuit region respectively. The insulating layer is disposed on the substrate and in the non-display region. The metal wall is disposed on the insulating layer and in the outer region, wherein a Poisson's ratio of the metal wall is greater than or equal to 0.32.

A display mother board of the disclosure includes a mother substrate that includes at least one display unit region and a cut region. The cut region is a region outside the display unit region. The display unit region includes a display panel, and the display panel includes a substrate, a pixel array, at least one driver circuit, an insulating layer, and a metal wall. The substrate includes a display region and a non-display region, and the non-display region has a driver circuit region and an outer region disposed outside the driver circuit region. The pixel array and the driver circuit are disposed in the display region and the driver circuit region respectively. The insulating layer is disposed on the substrate and in the non-display region. The metal wall is disposed on the insulating layer and in the outer region, wherein a Poisson's ratio of the metal wall is greater than or equal to 0.32.

Based on the above, in the display panel of the disclosure, the metal wall is disposed in the outer region outside the driver circuit region, and the Poisson's ratio of the metal wall is greater than or equal to 0.32. Therefore, the tensile strength of the display panel is improved by the metal wall. In particular, when the display mother board including a plurality of display panels is cut to form the individual display panels, the metal wall prevents cracks and/or peeling generated by cutting the edges from extending to the display region, so as to prevent cracks and/or peeling in the display region from breaking the metal wiring or damaging the substrate, thereby improving the reliability of the display panel.

To make the aforementioned and other features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a display mother board according to an embodiment of the disclosure.

FIG. 2 is a schematic top view of a display panel according to an embodiment of the disclosure.

FIG. 3 is a schematic top view illustrating another aspect of the display panel in the embodiment of FIG. 2.

FIG. 4 is a schematic cross-sectional view of a pixel structure in the display panel of FIG. 2.

FIG. 5A to FIG. 5C are schematic enlarged plan views illustrating partial regions of a metal wall of the display panel of the disclosure.

FIG. 6 is a schematic top view of a display panel according to another embodiment of the disclosure.

FIG. 7 is a schematic top view illustrating another aspect of the display panel in the embodiment of FIG. 6.

FIG. 8 is a schematic cross-sectional view of a partial external region of a display panel according to the first embodiment of the disclosure.

FIG. 9 is a schematic cross-sectional view of a partial external region of a display panel according to the second embodiment of the disclosure.

FIG. 10 is a schematic cross-sectional view of a partial external region of a display panel according to the third embodiment of the disclosure.

FIG. 11 is a schematic cross-sectional view of a partial external region of a display panel according to the fourth embodiment of the disclosure.

FIG. 12 is a schematic cross-sectional view of a partial external region of a display panel according to the fifth embodiment of the disclosure.

FIG. 13 is a schematic cross-sectional view of a partial external region of a display panel according to the sixth embodiment of the disclosure.

FIG. 14 is a schematic cross-sectional view of a partial external region of a display panel according to the seventh embodiment of the disclosure.

FIG. 15 is a schematic cross-sectional view of a partial external region of a display panel according to the eighth embodiment of the disclosure.

FIG. 16 is a schematic cross-sectional view of a partial external region of a display panel according to the ninth embodiment of the disclosure.

FIG. 17 is a schematic cross-sectional view of a partial external region of a display panel according to the tenth embodiment of the disclosure.

### DESCRIPTION OF THE EMBODIMENTS

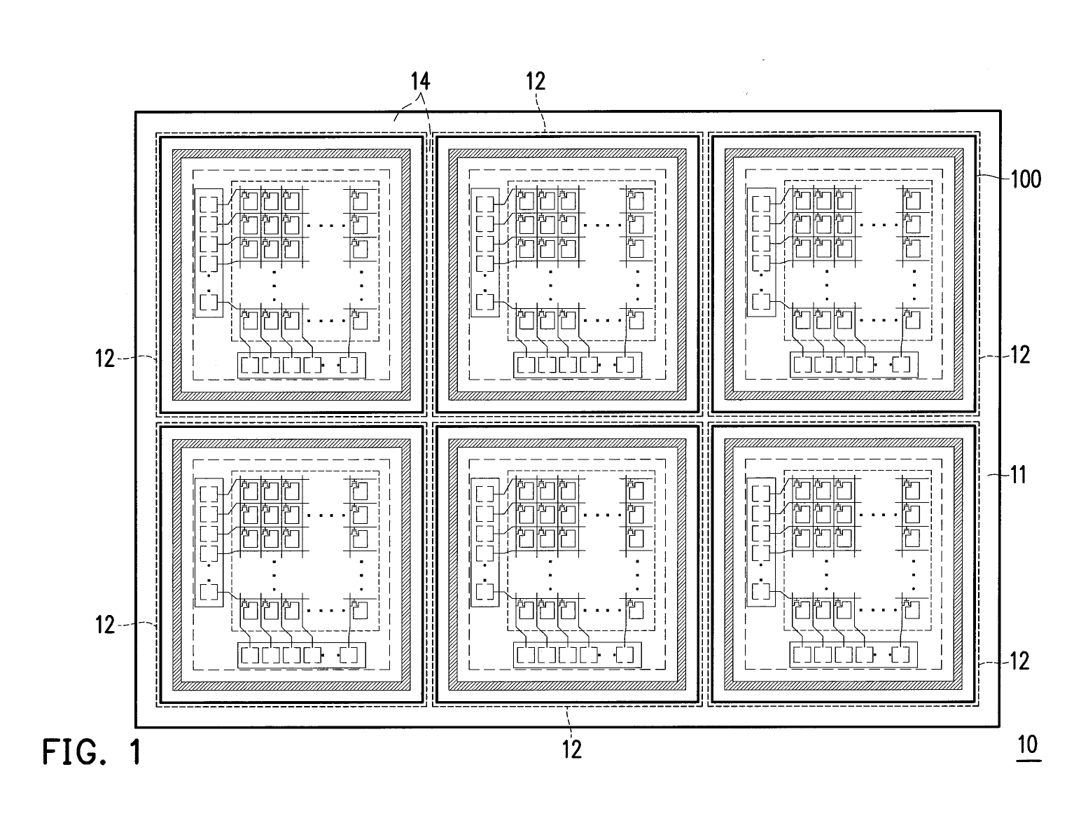

FIG. 1 is a schematic top view of a display mother board according to an embodiment of the disclosure. First, with reference to FIG. 1, a display mother board 10 includes a mother substrate 11 that includes at least one display unit region 12 and a cut region 14. Each display unit region 12 includes a display panel 100. In FIG. 1, six display unit regions 12 are depicted. However, the disclosure is not limited thereto. In other embodiments, the display unit regions 12 included in the disclosure can be any number. The cut region 14 is a region configured for separating two adjacent display unit regions 12 from each other, or separating the display unit region 12 at an edge from the mother substrate 11. Therefore, the cut region 14 is a region outside the display unit region 12. In other words, in order that the respective display panels 100 can be individually separated from the display mother board 10 in a cutting process successfully, the cut region 14 may be disposed between two adjacent display unit regions 12 and in any area outside and surrounding the display unit regions 12. According to the disclosure, a laser cutting process or a general blade cutting process, for example, is used to cut the cut region 14, so as to separate the display panels 100 from the display mother board 10. However, it is noted that the disclosure is not limited thereto. In addition, though not illustrated here, a plurality of cracks and/or a plurality of peeling spots may be generated in the cut region 14 during the aforementioned cutting process. These cracks and/or peeling spots extend into the display panels 100 from the cut edges.

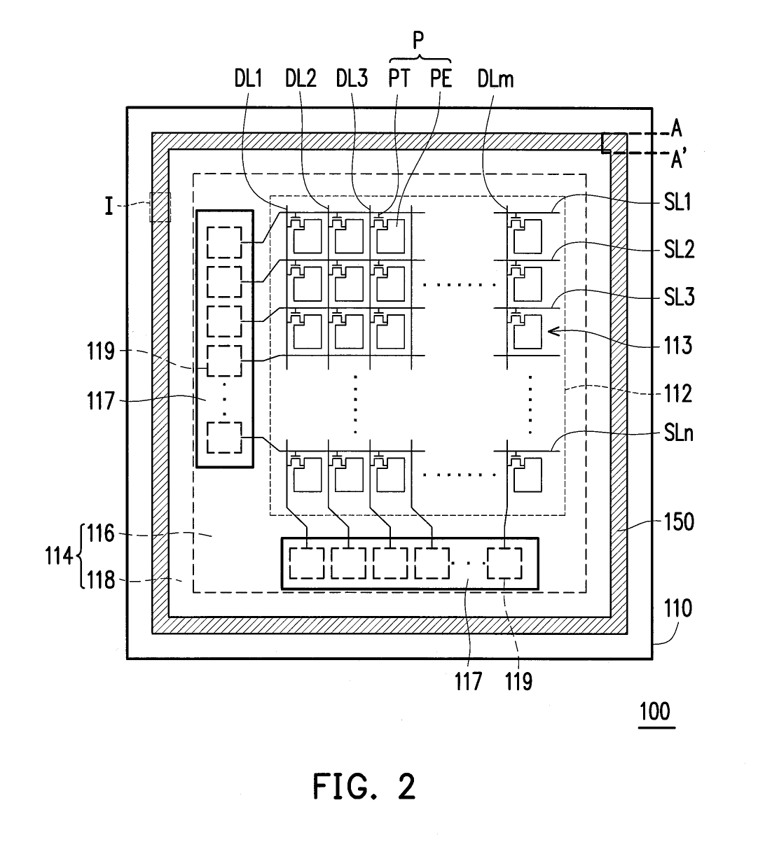

FIG. 2 is a schematic top view of a display panel according to an embodiment of the disclosure. Specifically, FIG. 2 is a schematic top view of one display panel that is cut from the display mother board of FIG. 1. With reference to FIG. 2, the display panel 100 includes a substrate 110, a pixel array 113, at least one driver circuit 117, and a metal wall 150. The substrate 110 includes a display region 112 and a non-display region 114, and the non-display region 114 has a driver circuit region 116 and an outer region 118 disposed outside the driver circuit region 116.

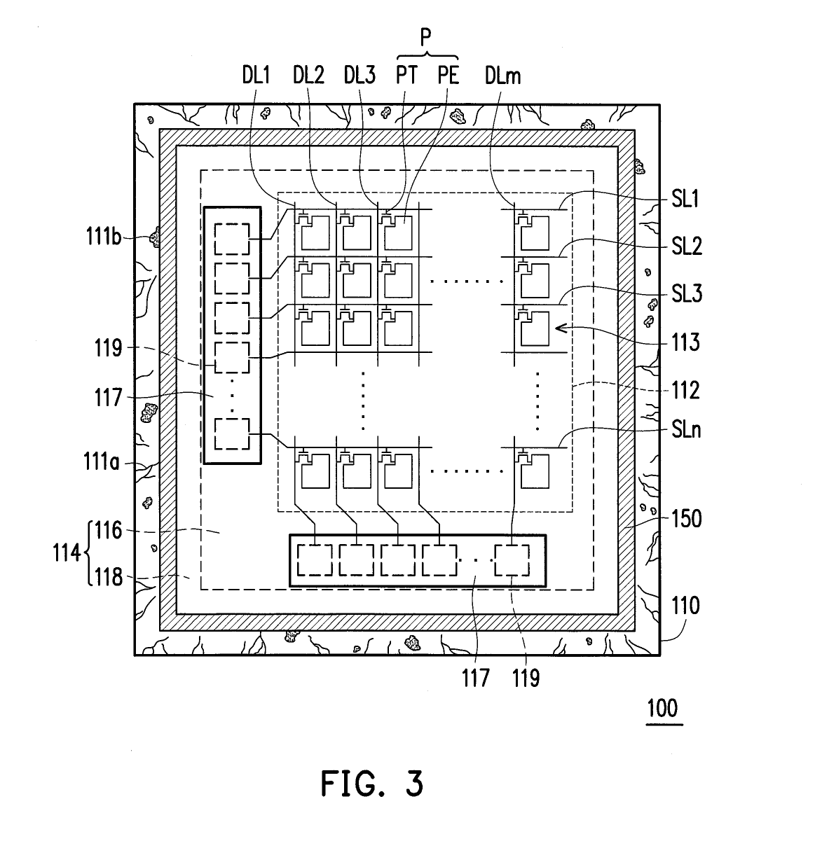

FIG. 3 is a schematic top view illustrating another aspect of the display panel in the embodiment of FIG. 2. With reference to FIG. 3, after cutting the display panel 100 from the display mother board 10 of FIG. 1, a tensile stress generated by the cutting process may cause a plurality of cracks 111a or a plurality of peeling spots 111b at the edges of the substrate 110, wherein the peeling spots 111b may be spots formed after peeling of a surface of the substrate 110. The cracks 111a or the peeling spots 111b may extend inward from the edges of the substrate 110. The cracks 111a or the peeling spots 111b end at the metal wall 150. Although the cracks 111a or the peeling spots 111b are caused by the tensile stress of the cutting process in this embodiment, similar cracks or peeling spots may also occur at the edges of the substrate 110 when the display panel 100 receives other types of stresses.

With reference to FIG. 2, the pixel array 113 is disposed on the substrate 110 and located in the display region 112. The pixel array 113 includes a plurality of scan lines SL1˜SLn, a plurality of data lines DL1˜DLm, and a plurality of pixel structures P. The scan lines SL1˜SLn and the data lines DL1˜DLm are disposed to intersect each other, and an insulting layer is disposed between the scan lines SL1˜SLn and the data lines DL1˜DLm. In other words, an extending direction of the scan lines SL1˜SLn is not parallel to an extending direction of the data lines DL1˜DLm. Preferably, the extending direction of the scan lines SL1˜SLn is perpendicular to the extending direction of the data lines DL1˜DLm. Considering conductivity, generally the scan lines SL1˜SLn and the data lines DL1˜DLm are formed using a metal material. However, the disclosure is not limited thereto. In other embodiments, the scan lines SL1˜SLn and the data lines DL1˜DLm may be fabricated using other conductive materials, such as an alloy, a nitride of the metal material, an oxide of the metal material, a nitrogen oxide of the metal material, other suitable materials, or a stack layer of the metal material and other conductive materials, for example. The pixel structure P includes a pixel active device PT and a pixel electrode PE, wherein the pixel active device PT is electrically connected with one corresponding scan line SL1˜SLn and one corresponding data line DL1˜DLm. Moreover, the pixel active device PT is electrically with the pixel electrode PE. A schematic cross-sectional view of the pixel structure P is provided below to further explain the pixel structure P.

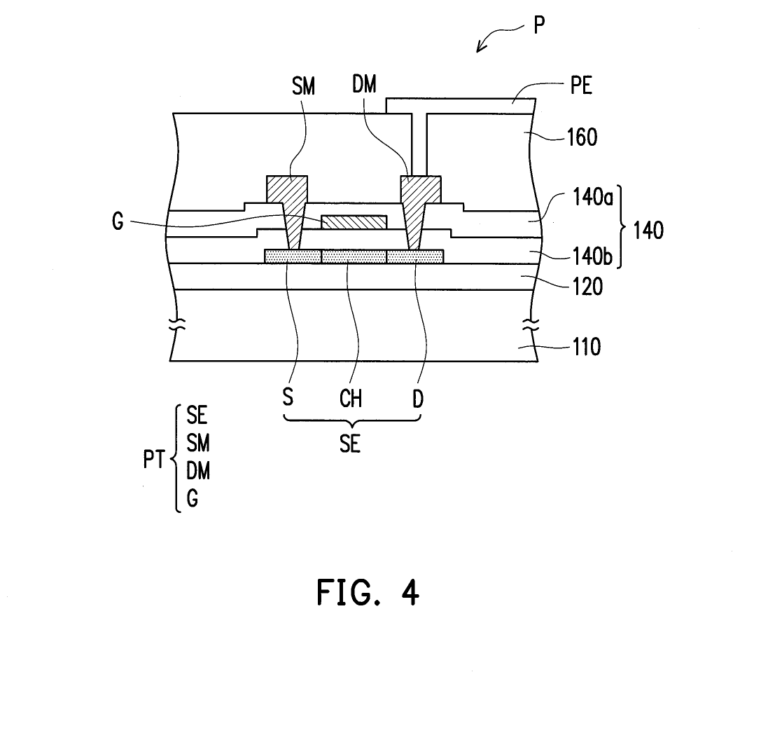

FIG. 4 is a schematic cross-sectional view of a pixel structure in the display panel of FIG. 2. According to the schematic cross-sectional view of FIG. 4, the pixel structure P includes the substrate 110, a buffer layer 120, an insulating layer 140, a flat layer 160, the pixel active device PT, and the pixel electrode PE. The buffer layer 120 is disposed on the substrate 110 and may be an inorganic thin film formed of an inorganic material, and a material used for forming the buffer layer 120 is usually an insulating material. The insulating layer 140 is disposed on the buffer layer 120 and includes a first sub-insulating layer 140a and a second sub-insulating layer 140b. A material of the first sub-insulating layer 140a and the second sub-insulating layer 140b may be silicon oxide, silicon nitride, or other insulating materials, for example. The flat layer 160 is disposed on the insulating layer 140, and a material of the flat layer 160 may include various suitable organic materials. The pixel active device PT may be a low temperature polysilicon thin film transistor (LTPS-TFT), for example, and the pixel active device PT may include a semiconductor layer SE, a source metal SM, a drain metal DM, and a gate G. The semiconductor layer SE is disposed on the buffer layer 120, and a material of the semiconductor layer SE is polysilicon, amorphous silicon, metal oxide semiconductor, or other semiconductor materials, for example. The semiconductor layer SE may include a source region S, a drain region D, and a channel region CH. A portion of the source metal SM and a portion of the drain metal DM are disposed on the insulating layer 140 while the rest of the source metal SM and the rest of the drain metal DM respectively penetrate the first sub-insulating layer 140a to be in contact with the semiconductor layer SE of the source region S and the drain region D. The pixel active device PT is LTPS-TFT in this embodiment. However, in other embodiments, the pixel active device PT may be other types of transistors.

With reference to FIG. 2 again, at least one driver circuit 117 is disposed on the substrate 110 and located in the driver circuit region 116. Each driver circuit 117 includes a plurality of driver circuit units 119, and each of the driver circuit units 119 is electrically connected with one data line DLm or one scan line SLn in the pixel array 113. In FIG. 2, two driver circuits are illustrated at the left side and the lower side of the pixel array as an example. However, the disclosure is not limited thereto. In other embodiments, one or two or more driver circuits may be included in the disclosure.

The metal wall 150 is disposed on the substrate 110 and located in the outer region 118. In this embodiment, the metal wall 150 may be an annular metal wall, for example, which is disposed in the outer region 118 and surrounds the non-display region 114. In addition, although not illustrated in FIG. 2, according to the disclosure, at least a portion of the metal wall 150 is disposed on the insulating layer for preventing short circuit of the display panel 100 resulting from electrical connection between the metal wall 150 and other conductive layers on the substrate 110.

The metal wall 150 may be formed of a single-layer or multi-layer metal material or alloy material, wherein a Poisson's ratio of the metal wall is greater than or equal to 0.32. For example, a material of the metal wall 150 may include Ti, Ta, Cu, Al, V, Ag, Pt, Pb, Au, or a combination of the foregoing. In the disclosure, the Poisson's ratio is defined as a ratio of a lateral deformation amount to a vertical deformation amount of a material when the material receives a tensile or compressive force. Those skilled in the art should understand that the Poisson's ratio has a relationship of

$$G = \frac{E}{2 ( 1 + v )}$$

with respect to each mechanical modulus, wherein ν represents the Poisson's ratio, G represents a shear modulus, and E represents a Young's modulus.

The Poisson's ratio of the metal wall 150 is greater than or equal to 0.32, and the metal wall 150 is disposed in the outer region 118 of the display panel 100. Thus, when the cracks 111a or peeling spots 111b are generated at the edges of the display panel 100 due to the stress, the metal wall 150 ends the cracks 111a or peeling spots 111b outside the metal wall 150 and prevents the cracks 111a or the peeling spots 111b from extending to the display region 112 and the driver circuit region 116 of the display panel 100, thereby improving the reliability of the display panel 100.

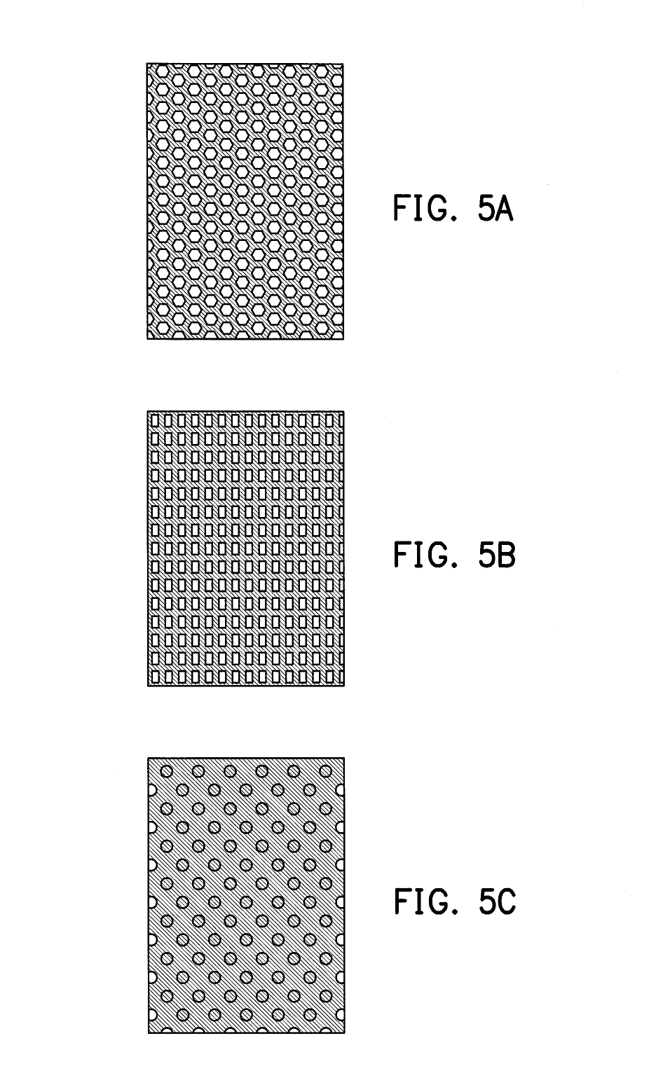

FIG. 5A to FIG. 5C are schematic enlarged plan views illustrating a partial region of the metal wall of the display panel of the disclosure, wherein the region illustrated by FIG. 5A to FIG. 5C is the region I of FIG. 2, for example. With reference to FIG. 5A to FIG. 5C, the metal wall 150 may be a metal wall having a honeycomb hole pattern (as shown in FIG. 5A), a metal wall having a grid pattern (as shown in FIG. 5B), or a metal wall having a porous pattern (as shown in FIG. 5C) for changing an extending direction of the cracks and/or peeling. More specifically, when the cracks and/or peeling extends inward from the external region of the display panel and reaches the metal wall 150, stresses in different directions may be applied to the cracks and/or peeling in accordance with the different patterns of the metal wall 150. Therefore, the metal wall 150 changes the extending direction of the cracks and/or peeling, so as to prevent the cracks and/or peeling from extending into the display panel.

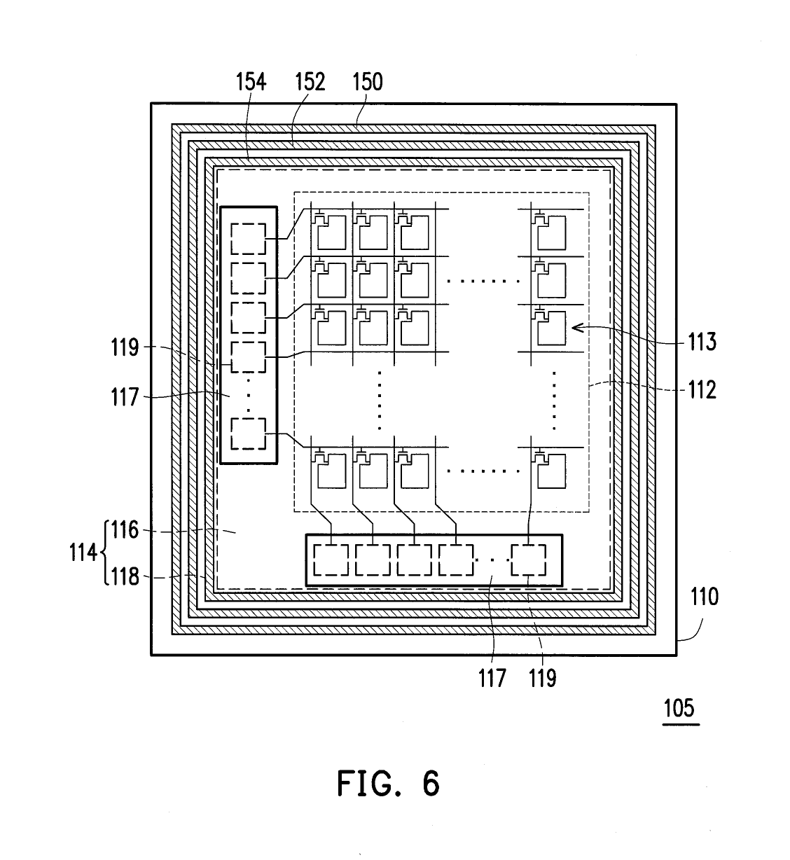

FIG. 6 is a schematic top view of a display panel according to another embodiment of the disclosure. With reference to FIG. 2 and FIG. 6, a display panel 105 of FIG. 6 is approximately the same as the display panel 100 of FIG. 2, and a difference therebetween lies in that: the display panel 105 further includes inner annular metal walls 152 and 154, and the metal wall 150 surrounds the inner annular metal walls 152 and 154. Similar to the metal wall 150, the inner annular metal walls 152 and 154 are disposed on the insulating layer and located in the outer region 118. In addition, although FIG. 6 depicts two inner annular metal walls, the disclosure may include only one or two or more inner annular metal walls. In other words, the display panel of the disclosure may include at least one inner annular metal wall.

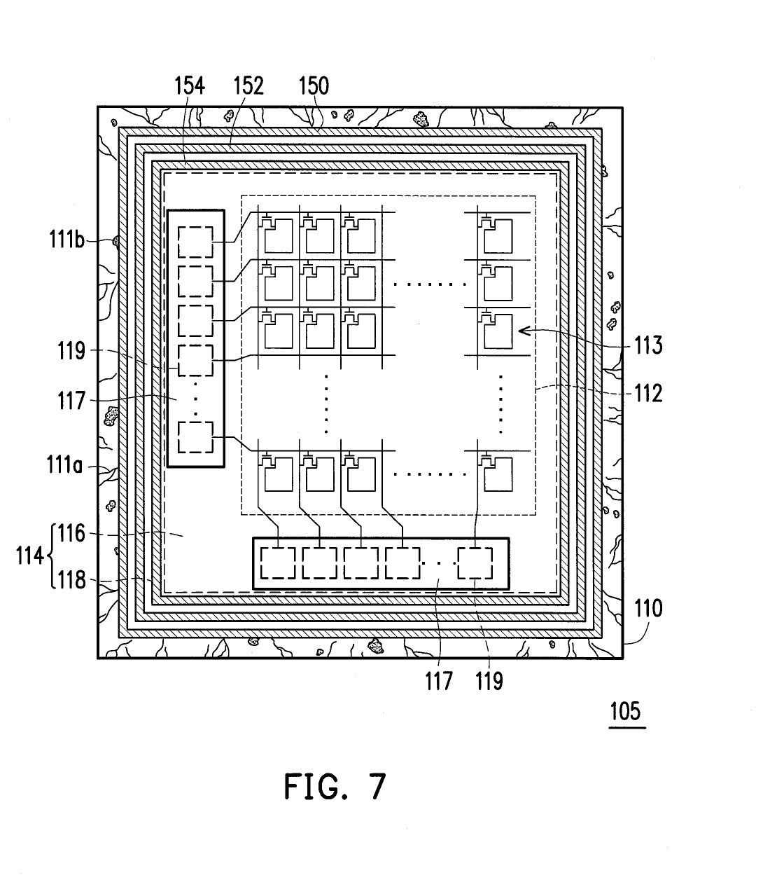

FIG. 7 is a schematic top view illustrating another aspect of the display panel in the embodiment of FIG. 6. With reference to FIG. 7, similar to the display panel 100, a plurality of the cracks 111a or a plurality of the peeling spots 111b may be generated at the edges of the substrate 110 when a tensile stress or other stresses are applied to the display panel 105 during cutting, wherein the cracks 111a or the peeling spots 111b may extend into the display panel 105. In this embodiment, because the display panel 105 is provided with the annular metal wall 150 and the inner annular metal walls 152 and 154, when the cracks 111a or the peeling spots 111b extend toward the inside of the display panel 105, the inner annular metal walls 152 and 154 besides the outmost metal wall 150 also prevent the cracks 111a or the peeling spots 111b from extending, thereby further improving the reliability of the display panel 105. Moreover, because the function of the inner annular metal walls 152 and 154 is to assist the metal wall 150 to prevent the cracks 111a or the peeling spots 111b from extending, the disclosure does not limit the Poisson's ratios of the inner annular metal walls 152 and 154, and the inner annular metal walls 152 and 154 may be fabricated using any suitable metal. Furthermore, the materials of the metal wall 150, the inner annular metal wall 152, and the inner annular metal wall 154 may be the same, different, or not completely the same.

In addition, similar to the aspects of the metal walls illustrated in FIG. 5A to FIG. 5C, the inner annular metal walls 152 and 154 in the display panel 105 of FIG. 6 (or FIG. 7) may respectively have the honeycomb hole pattern, the grid pattern, or the porous pattern, wherein the inner annular metal walls 152 and 154 may have the same or different patterns. Moreover, the patterns of the metal wall 150 and the inner annular metal walls 152 and 154 may be the same, different, or not completely the same. In other words, the metal wall 150 and the inner annular metal walls 152 and 154 may be formed to have different patterns for preventing various cracks and/or peeling spots from extending into the display panel; or the metal wall 150 and the inner annular metal walls 152 and 154 may be formed to have the same pattern for preventing specific types of cracks and/or peeling spots from extending into the display panel, so as to improve the reliability of the display panel 105.

Several embodiments are given below to clearly illustrate the structure of the display panel of the disclosure. However, it should be understood that the following embodiments are merely examples of the disclosure and should not be construed as limitations to the disclosure.

### First Embodiment

FIG. 8 is a schematic cross-sectional view of a partial external region of a display panel according to the first embodiment of the disclosure. Specifically, FIG. 8 is a schematic cross-sectional view taken along the line A-A′ of FIG. 2. With reference to FIG. 2 and FIG. 8, the outer region 118 of the display panel 100 includes the substrate 110, the buffer layer 120, the semiconductor layer 130, the insulating layer 140, and the metal wall 150. A material of the substrate 110 may be an organic polymer, glass, quartz, an opaque/reflective material (e.g. conductive material, metal, wafer, ceramics, or other suitable materials), or other suitable materials.

The buffer layer 120 is disposed on the substrate 110 and may be an inorganic thin film formed of an inorganic material. For example, the buffer layer 120 may be an inorganic thin film of silicon oxide and silicon nitride, for example, which has a thickness of about 350 nm, wherein a thickness of the silicon oxide is about 300 nm and a thickness of the silicon nitride is about 50 nm. In addition to the outer region 118, the buffer layer 120 may be further disposed in other regions of the display panel 110 to serve as one layer that constitutes the active device and/or passive device. That is to say, the buffer layer 120 in the outer region 118 may be the layer that is retained after forming the active device and/or passive device in other regions. For example, the buffer layer 120 in the outer region 118 and the buffer layer 120 in the pixel structure P of FIG. 4 may be the same layer formed by the same fabricating process. Therefore, when forming the pixel structure in the display region, the buffer layer 120 in the outer region 118 can be formed without performing an additional fabricating process.

The semiconductor layer 130 may be disposed on the buffer layer 120. In the non-display region 114 of the display panel 110, the semiconductor layer 130 may be disposed only in the outer region 118 and not extend to the driver circuit region 116, such that the driver circuit 117 is not electrically connected with the semiconductor layer 130 to cause short circuit. Moreover, a material of the semiconductor layer 130 is polysilicon, amorphous silicon, a metal oxide semiconductor, or other semiconductor materials, which has a thickness of about 10 nm to 200 nm. It is worth mentioning that, according to the disclosure, the semiconductor layer 130 is optional. That is, in other embodiments, the outer region 118 of the display panel 110 may not include the semiconductor layer 130. In addition, the semiconductor layer 130 and the semiconductor layer SE in the pixel structure P of FIG. 4 may be simultaneously formed in the same fabricating process. That is to say, when forming the pixel structure in the display region, the semiconductor layer 130 can be simultaneously formed in the outer region 118 without performing an additional fabricating process.

The insulating layer 140 is disposed on the semiconductor layer 130 and located in the non-display region 114 of the substrate 110. The insulating layer 140 may be an inorganic thin film formed of silicon oxide and silicon nitride, for example, which has a thickness of about 600 nm. For example, the insulating layer 140 is an inorganic thin film including silicon oxide of about 300 nm and silicon nitride of about 300 nm. In addition to the outer region 118, the insulating layer 140 may be further disposed in other regions of the display panel 110 to serve as one layer that constitutes the active device and/or passive device. That is to say, the insulating layer 140 in the outer region 118 may be the layer that is retained after forming the active device and/or passive device in other regions. For example, the insulating layer 140 in the outer region 118 and the insulating layer 140 in the pixel structure P of FIG. 4 may be the same layer formed by the same fabricating process. Therefore, when forming the pixel structure in the display region, the insulating layer 140 in the outer region 118 can be formed simultaneously without performing an additional fabricating process.

The metal wall 150 is disposed on the insulating layer 140 and located in the outer region 118. The Poisson's ratio of the metal wall 150 is greater than or equal to 0.32, and the thickness of the metal wall 150 is about 50 nm to 1000 nm, for example. A material of the metal wall 150 may include Ti, Ta, Cu, Al, V, Ag, Pt, Pb, Au, or a combination of the foregoing. Although the metal wall 150 is a single-layer metal structure in this embodiment, the disclosure is not limited thereto. In other embodiments, the metal wall 150 may also be a multi-layer metal stack structure. Moreover, the metal wall 150 and the source metal SM and the drain metal DM in the pixel structure P of FIG. 4 may be formed simultaneously in the same fabricating process. That is, when forming the pixel structure in the display region, the metal wall 150 can be simultaneously formed in the outer region 118 without performing an additional fabricating process.

In this embodiment, because the Poisson's ratio of the metal wall is greater than or equal to 0.32, when the metal wall is disposed in the outer region of the display panel, the tensile strength of the display panel is improved to prevent cracks or peeling from extending to the display region or the driver circuit region. Furthermore, because the material and forming method of the metal wall are the same as those of the active device/passive device in the display panel, the metal wall is formed without additional fabricating processes.

### Second Embodiment

FIG. 9 is a schematic cross-sectional view of a partial external region of a display panel according to the second embodiment of the disclosure. With reference to FIG. 8 and FIG. 9, the structure of a display panel 200 of the second embodiment is similar to the structure of the first embodiment, and a difference therebetween lies in that: a metal wall 250 in the display panel 200 is directly disposed on the buffer layer 120. In other words, in the external region of the display panel 200, the buffer layer 120 is disposed directly on the substrate 110 to serve as the insulating layer without disposing the semiconductor layer and the additional insulating layer. Therefore, the metal wall 250 may be directly disposed on the buffer layer 120 that serves as the insulating layer. It is worth mentioning that, because the buffer layer 120 is usually an inorganic thin film formed of an inorganic material and having electrically insulating properties, when the metal wall 250 is disposed directly on the buffer layer 120, the metal wall 250 does not form electrical connection with other conductive layers to cause short circuit.

### Third Embodiment

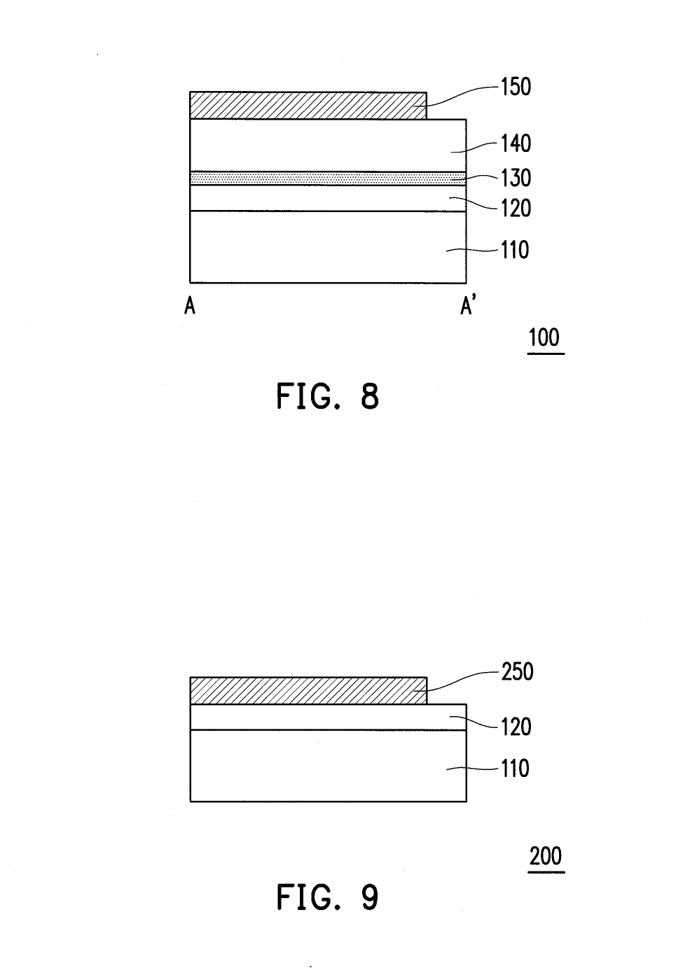

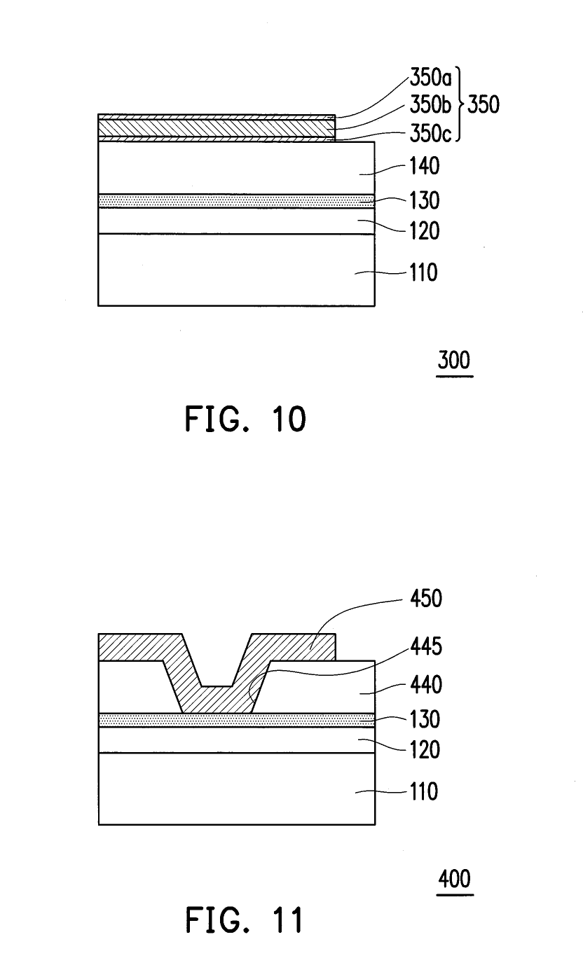

FIG. 10 is a schematic cross-sectional view of a partial external region of a display panel according to the third embodiment of the disclosure. With reference to FIG. 8 and FIG. 10, the structure of a display panel 300 of the third embodiment is mostly the same as the structure of the first embodiment and a difference therebetween lies in that: a metal wall 350 of the display panel 300 is a multi-layer metal stack structure.

With reference to FIG. 10, for example, the metal wall 350 is a metal stack structure formed of a metal layer 350a, a metal layer 350b, and a metal layer 350c, wherein the metal layer 350a/the metal layer 350b/the metal layer 350c may be a multi-layer metal stack structure of Ti/Al/Ti or Mo/Al/Mo, for example. It is worth mentioning that the metal wall 350 may include a metal layer (e.g. Mo) having a Poisson's ratio smaller than 0.32 as long as an average Poisson's ratio of all the metal layers in the metal wall 350 is greater than 0.32. For example, in the embodiment where the metal wall 350 is the metal stack structure of Mo/Al/Mo, as long as the thickness of the Al metal layer occupies 50% or more of the overall thickness of the metal wall 350, the Poisson's ratio of the metal wall 350 is greater than 0.32, which falls within the scope of the disclosure. Moreover, in other embodiments, the metal wall 350 may be a multi-layer metal stack structure of two metal layers or four metal layers or more, other than three layers.

In this embodiment, because the metal wall may be a multi-layer metal stack structure and include metal layers having lower ductility, the metal wall can be fabricated by various processes that are usually used for forming metal layers in the display panel. Thus, formation of the metal wall does not require additional metal processing. Accordingly, the production costs are reduced and the fabricating processes are simplified.

### Fourth Embodiment

FIG. 11 is a schematic cross-sectional view of a partial external region of a display panel according to the fourth embodiment of the disclosure. With reference to FIG. 8 and FIG. 11, the structure of a display panel 400 of the fourth embodiment is mostly the same as the structure of the first embodiment and a difference therebetween lies in that: an insulating layer 440 of the display panel 400 has an opening 445, and a metal wall 450 is filled in the opening 445, wherein the opening 445 may be a trench between two sidewalls of the insulating layer 440. In addition, with reference to the third embodiment, the metal wall 450 of this embodiment may also be a multi-layer metal stack structure.

### Fifth Embodiment

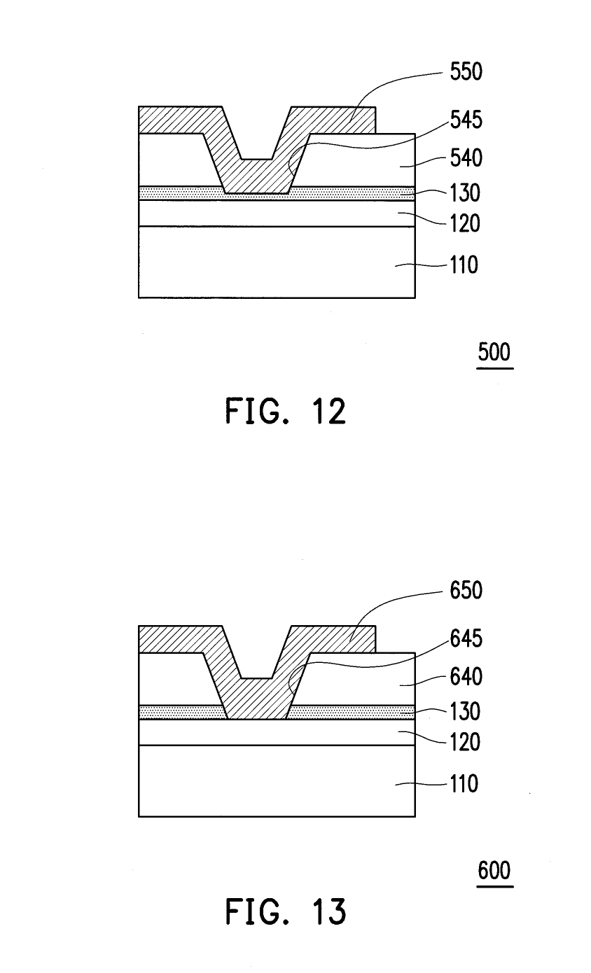

FIG. 12 is a schematic cross-sectional view of a partial external region of a display panel according to the fifth embodiment of the disclosure. With reference to FIG. 11 and FIG. 12, the structure of a display panel 500 of the fifth embodiment is mostly the same as the structure of the fourth embodiment and a difference therebetween lies in that: an opening 545 extends into a portion of the semiconductor layer 130, and a metal wall 550 is filled in the opening 545 to be in contact with the semiconductor layer 130.

### Sixth Embodiment

FIG. 13 is a schematic cross-sectional view of a partial external region of a display panel according to the sixth embodiment of the disclosure. With reference to FIG. 11 and FIG. 13, the structure of a display panel 600 of the sixth embodiment is mostly the same as the structure of the fourth embodiment and a difference therebetween lies in that: an opening 645 further penetrates the semiconductor layer 130 to expose the buffer layer 120, and a metal wall 650 is filled in the opening 645 to be in contact with the buffer layer 120.

In the fourth embodiment to the sixth embodiment, the opening may be formed in the insulating layer by dry etching, for example, and a depth of the opening may be controlled by controlling the etching conditions of the dry etching process. For example, in the fourth embodiment of FIG. 11, the opening 445 exposes an upper surface of the semiconductor layer 130; in the fifth embodiment of FIG. 12, the depth of the opening 545 may be increased by prolonging the etching process, such that the opening 545 extends into a portion of the semiconductor layer 130; and in the sixth embodiment of FIG. 13, the opening 645 is formed to penetrate the semiconductor layer 130 and expose the buffer layer 120. It is worth mentioning that, because the materials of the insulating layer and the buffer layer (e.g. silicon oxide and/or silicon oxide) are different from the material of the semiconductor layer (e.g. polysilicon and amorphous silicon), the depth of the opening can be determined easily by using the etching selectivity between the materials of the layers.

The metal wall may be disposed differently corresponding to the difference of the depth of the opening. For example, in the fourth embodiment of FIG. 11, the opening 445 exposes the upper surface of the semiconductor layer 130, and thus the metal wall 450 is filled in the opening 445 to be in contact with the semiconductor layer 130; in the fifth embodiment of FIG. 12, the opening 545 extends into a portion of the semiconductor layer 130, and thus the metal wall 550 is filled in the opening 545 to be in contact with the partially etched semiconductor layer 130; and in the sixth embodiment of FIG. 13, the opening 645 penetrates the semiconductor layer 130 to expose the buffer layer 120, and thus the metal wall 650 is in contact with the buffer layer 120 exposed by the opening 645.

In the above embodiments, the opening is formed in the insulating layer by the etching process. Therefore, the thickness of the insulating layer is reduced to improve the tensile strength of the display panel. In other words, because the thickness of the inorganic thin film in this embodiment is reduced, the tensile strength of the display panel is further improved. In addition, because the opening is formed in the insulating layer in this embodiment, when the cracks or peeling extends inward from the outside of the display panel, the metal wall in the insulating layer effectively prevents the cracks and/or peeling from extending into the display panel along the insulating layer (or inorganic thin film).

### Seventh Embodiment

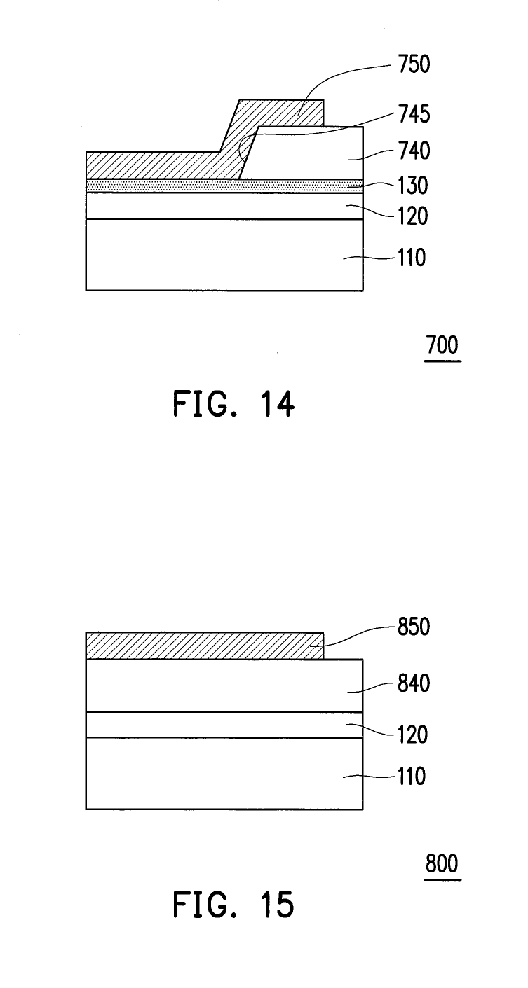

FIG. 14 is a schematic cross-sectional view of a partial external region of a display panel according to the seventh embodiment of the disclosure. With reference to FIG. 8 and FIG. 14, the structure of a display panel 700 of the seventh embodiment is mostly the same as the structure of the first embodiment and a difference therebetween lies in that: an insulating layer 740 of the display panel 700 has an opening 745, and a metal wall 750 is filled in the opening 745, wherein the opening 745 of the insulating layer 740 is an open opening having a single sidewall. In addition, with reference to the third embodiment, the metal wall 750 of this embodiment may be a metal wall having a multi-layer metal stack structure.

In the seventh embodiment, the insulating layer 740 has the opening 745, and the opening 745 is an open opening having a single sidewall, formed by a sidewall of the insulating layer 740. In addition, the depth of the opening 745 may be controlled by controlling the etching conditions and the etching selectivity between the layers, so as to control the opening 745 to expose the upper surface of the semiconductor layer 130, to extend into a portion of the semiconductor layer 130, or to penetrate the semiconductor layer 130 to expose the buffer layer 120.

Although FIG. 14 illustrates that the opening 745 exposes the upper surface of the semiconductor layer 130 and the metal wall 750 is filled in the opening 745 to be in contact with the semiconductor layer 130 in this embodiment, the disclosure is not limited thereto. In other embodiments, because the opening 745 may extend into a portion of the semiconductor layer 130 or may penetrate the semiconductor layer 130 to expose the buffer layer 120, the metal wall 750 may be filled in the opening 745 to be in contact with the partially etched semiconductor layer 130 or the buffer layer 120 exposed by the opening 745.

In this embodiment, the open opening formed by the etching process reduces the thickness of a large area of the insulating layer. Thus, the tensile strength of the substrate is further improved. Moreover, because the metal wall is formed directly on an outer sidewall of the insulating layer with respect to the display region, when cracks and/or peeling occurs on the outer side of the display panel, the cracks and/or peeling is only in contact with the metal wall, not the insulating layer, and thus the metal wall prevents the cracks and/or the peeling spots from extending to the display region and the driver circuit region inside the display panel through the insulating layer.

### Eighth Embodiment

FIG. 15 is a schematic cross-sectional view of a partial external region of a display panel according to the eighth embodiment of the disclosure. With reference to FIG. 8 and FIG. 15, the structure of a display panel 800 of the eighth embodiment is mostly the same as the structure of the first embodiment and a difference therebetween lies in that: an insulating layer 840 of the display panel 800 is disposed directly on the buffer layer 120. In addition, with reference to the third embodiment, a metal wall 850 of this embodiment may be a metal wall having a multi-layer metal stack structure.

In this embodiment, the insulating layer 840 of the external region of the display panel 800 is disposed directly on the buffer layer 120. Thus, the semiconductor layer in the external region is not electrically connected with other conductive layers in the display region or the driver circuit region to cause short circuit of the display panel 800.

### Ninth Embodiment

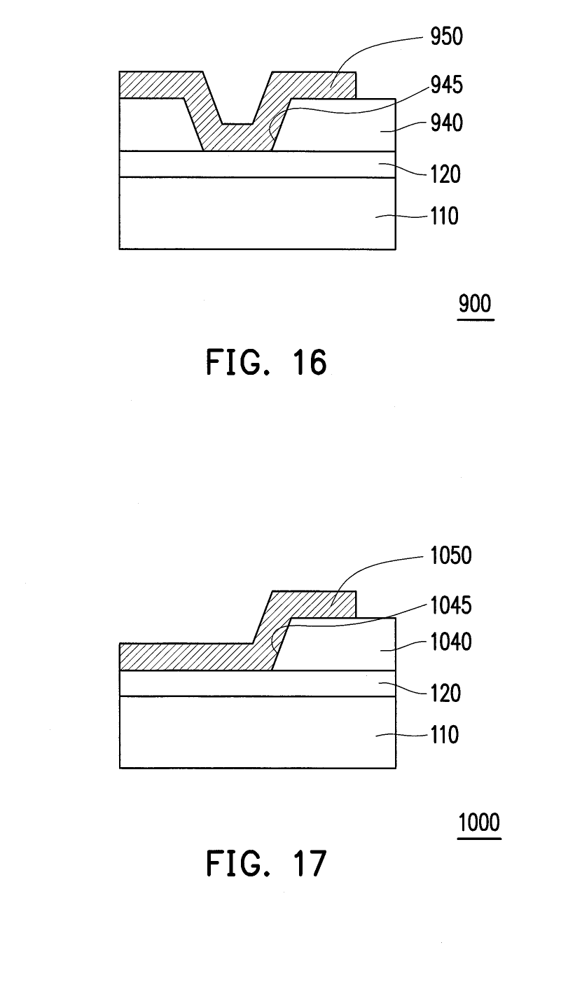

FIG. 16 is a schematic cross-sectional view of a partial external region of a display panel according to the ninth embodiment of the disclosure. With reference to FIG. 8 and FIG. 16, the structure of a display panel 900 of the ninth embodiment is mostly the same as the structure of the first embodiment and a difference therebetween lies in that: an insulating layer 940 of the display panel 900 is disposed directly on the buffer layer 120; and the insulating layer 940 has an opening 945, and a metal wall 950 is filled in the opening 945, wherein the opening 945 may be a trench between two sidewalls of the insulating layer 940. In addition, with reference to the third embodiment, the metal wall 950 of this embodiment may be a metal wall having a multi-layer metal stack structure.

In the ninth embodiment, because no semiconductor layer is disposed in the external region of the display panel 900, the opening 945 of the insulating layer 940 directly exposes the upper surface of the buffer layer 120, and the metal wall 950 is filled in the opening 945 to be in contact with the upper surface of the buffer layer 120. However, the disclosure is not limited thereto. More specifically, in other embodiments, the depth of the opening 945 may be controlled by controlling the etching conditions of the etching process, such that the opening 945 extends into a portion of the buffer layer 120, and the metal wall 950 is filled in the opening 945 to be in contact with the partially etched buffer layer 120.

### Tenth Embodiment

FIG. 17 is a schematic cross-sectional view of a partial external region of a display panel according to the tenth embodiment of the disclosure. With reference to FIG. 8 and FIG. 17, the structure of a display panel 1000 of the tenth embodiment is mostly the same as the structure of the first embodiment and a difference therebetween lies in that: an insulating layer 1040 of the display panel 1000 is directly disposed on the buffer layer 120; and the insulating layer 1040 has an opening 1045, and a metal wall 1050 is filled in the opening 1045, wherein the opening 1045 is an open opening having a single sidewall, formed by a sidewall of the insulating layer 1040. In addition, with reference to the third embodiment, the metal wall 1050 of this embodiment may be a metal wall having a multi-layer metal stack structure.

In the tenth embodiment, no semiconductor layer is disposed in the external region of the display panel 1000. Thus, the opening 1045 of the insulating layer 1040 directly exposes the upper surface of the buffer layer 120, and the metal wall 1050 is filled in the opening 1045 to be in contact with the upper surface of the buffer layer 120. Moreover, the depth of the opening 1045 is controlled by controlling the etching conditions, such that the opening 1045 is controlled to extend into a portion of the buffer layer 120, and the metal wall 1050 is filled in the opening 1045 to be in contact with the partially etched buffer layer 120.

In the eighth embodiment to the tenth embodiment, no semiconductor layer is disposed in the external region of the display panel. Therefore, the semiconductor layer in the external region is not electrically connected with other conductive layers in the display region or the driver circuit region to cause short circuit of the display panel. Accordingly, the reliability of the display panel is further improved.

To sum up, according to the disclosure, the metal wall is disposed in the external region of the display panel, and the Poisson's ratio of the metal wall is greater than or equal to 0.32. Therefore, when stress is applied to the display panel to cause cracks and/or peeling at the edges of the substrate, the cracks and/or peeling is blocked by the metal wall and does not extend into the display panel. In particular, during the process of cutting the display panel from the mother board, the metal wall prevents the cracks and/or peeling from extending to the work region of the display panel, thereby improving the reliability of the display panel. In addition, the disclosure further improves the tensile strength of the display panel by increasing the number of the metal walls and changing the configuration relationship between the metal walls and other layers. Furthermore, because the material and forming method of the metal wall are the same as those of the active device/passive device in the display panel, the metal wall of the disclosure can be formed without additional fabricating processes.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display panel, comprising:
a substrate comprising a display region and a non-display region, wherein the non-display region comprises a driver circuit region and an outer region located outside the driver circuit region;
a pixel array and at least one driver circuit disposed in the display region and the driver circuit region respectively;
an insulating layer disposed on the substrate and located in the non-display region; and
a metal wall disposed on the insulating layer and located in the outer region, wherein a Poisson's ratio of the metal wall is greater than or equal to 0.32.

2. The display panel according to claim 1, wherein an edge of the substrate has a plurality of cracks or a plurality of peeling spots, and the cracks or the peeling spots end at the metal wall.

3. The display panel according to claim 1, further comprising:
a buffer layer disposed on the substrate; and
a semiconductor layer disposed on the buffer layer, wherein the insulating layer is disposed on the semiconductor layer, and the semiconductor layer is located in the outer region and does not extend into the driver circuit region.

4. The display panel according to claim 3, wherein the insulating layer comprises an opening, and the metal wall is filled in the opening.

5. The display panel according to claim 4, wherein the opening exposes the semiconductor layer, and the metal wall is filled in the opening to be in contact with the semiconductor layer.

6. The display panel according to claim 4, wherein the opening further extends into a portion of the semiconductor layer, and the metal wall is filled in the opening to be in contact with the semiconductor layer.

7. The display panel according to claim 4, wherein the opening further penetrates the semiconductor layer to expose the buffer layer, and the metal wall is filled in the opening to be in contact with the buffer layer.

8. The display panel according to claim 4, wherein the opening is a trench or an open opening with a single sidewall.

9. The display panel according to claim 1, further comprising a buffer layer disposed on the substrate, wherein the insulating layer is disposed on the buffer layer and comprises an opening, and the metal wall is filled in the opening.

10. The display panel according to claim 9, wherein the opening penetrates the insulating layer to expose the buffer layer, and the metal wall is filled in the opening to be in contact with the buffer layer.

11. The display panel according to claim 9, wherein the opening penetrates the insulating layer and the opening extends into a portion of the buffer layer, and the metal wall is filled in the opening to be in contact with the buffer layer.

12. The display panel according to claim 9, wherein the opening is a trench or an open opening with a single sidewall.

13. The display panel according to claim 1, wherein a material of the metal wall comprises Ti, Ta, Cu, Al, V, Ag, Pt, Pb, Au, or a combination of the above.

14. The display panel according to claim 1, further comprising at least one inner annular metal wall disposed on the insulating layer and located in the outer region, wherein the metal wall surrounds the at least one inner annular metal wall.

15. The display panel according to claim 1, wherein the metal wall is a single-layer metal structure or a multi-layer metal stack structure.

16. The display panel according to claim 1, wherein the metal wall is a multi-layer metal stack structure of Ti/Al/Ti or Mo/Al/Mo.

17. The display panel according to claim 1, wherein the metal wall is a metal wall having a honeycomb hole pattern, a metal wall having a grid pattern, or a metal wall having a porous pattern.

18. A display mother board, comprising:
a mother substrate comprising at least one display unit region and a cut region, wherein the cut region is a region outside the at least one display unit region, and each of the at least one display unit region comprises a display panel, the display panel respectively comprising:
a substrate comprising a display region and a non-display region, wherein the non-display region comprises a driver circuit region and an outer region located outside the driver circuit region;
a pixel array and at least one driver circuit disposed in the display region and the driver circuit region respectively;
an insulating layer disposed on the substrate and located in the non-display region; and
a metal wall disposed on the insulating layer and located in the outer region, wherein a Poisson's ratio of the metal wall is greater than or equal to 0.32.

19. The display mother board according to claim 18, wherein a material of the metal wall comprises Ti, Ta, Cu, Al, V, Ag, Pt, Pb, Au, or a combination of the above.

20. The display mother board according to claim 18, further comprising at least one inner annular metal wall disposed on the insulating layer and located in the outer region, wherein the metal wall surrounds the at least one inner annular metal wall.
